(19) United States
(12) Patent Application Publication
(10) Pub. No.: US 2008/0173899 A1
(43) Pub. Date: Jul. 24, 2008

(54) SEMICONDUCTOR DEVICE

(76) Inventors: Koichiro TAKAKUWA, Tokyo (JP); Kazuo Tanaka, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/970,512

(22) Filed: Jan. 7, 2008

(30) Foreign Application Priority Data
Jan. 22, 2007 (JP) 2007-011661

(51) Int. Cl. H01L 27/10

(52) U.S. Cl. 257/203; 257/E27.07

(57) ABSTRACT

There is provided a technology which allows sufficient protection of internal circuits from electrostatic discharge even when internal-circuit power source pads and internal-circuit GND pads are formed on an internal circuit region. Internal-circuit power source pads and internal-circuit GND pads are placed in the core region of a semiconductor chip. Between the internal-circuit power source pads and the internal-circuit GND pads, the internal circuits are formed. Between the internal-circuit power source pads and the internal-circuit GND pads, electrostatic protection circuits for protecting the internal circuits from a surge current are further formed. Each of the electrostatic protection circuits is composed of a discharge circuit for causing the surge current to flow therein and a control circuit for controlling the discharge circuit. The present invention is characterized in that the discharge circuits are placed in the core region and the control circuits are placed in an I/O region.

### CROSS-REFERENCE TO RELATED APPLICATIONS

The disclosure of Japanese Patent Application No. 2007-11661 filed on Jan. 22, 2007 including the specification, drawings and abstract is incorporated herein by reference in its entirety.

### BACKGROUND OF THE INVENTION

The present invention relates to a semiconductor device and, more particularly, to a technology which is effective when applied to a technology for electrostatic protection of a semiconductor device in which internal-circuit power source pads are placed in a region Other than an I/O region.

Japanese Unexamined Patent Publication No. 2006-100606 (Patent Document 1) discloses a technology for protecting a semiconductor device having a plurality of internal circuits operating at different voltages from an electrostatic breakdown occurring between the individual internal circuits. In particular, an RC-Timer protection circuit is used as an electrostatic protection circuit and placed in an internal circuit region (core region).

### [Patent Document 1]

### Japanese Unexamined Patent Publication No. 2006-100606

### SUMMARY OF THE INVENTION

Besides a memory product in which a DRAM (Dynamic Random Access Memory), an SRAM (Static Random Access Memory), a nonvolatile memory, or the like is formed in a semiconductor chip, semiconductor devices include a product termed a SOC (System On Chip). The SOC forms a system with a logic circuit, a microcomputer, and a memory mounted in a single semiconductor chip.

An example of the layout of the semiconductor chip composing the SOC is shown in FIG. 14. As shown in FIG. 14, a semiconductor chip 100 has a rectangular shape and a core region (internal circuit region) 101 in which internal circuits are formed in the center region thereof. In the peripheral portion of the semiconductor chip 100 surrounding the core region, an I/O region 102 is formed. In the I/O region 102, bonding pads and input/output circuits (I/O circuits) are formed. Specifically, the bonding pads include signal pads 103, internal-circuit power source pads 105a, internal-circuit GND pads 105b, I/O-circuit power source pads 107a, and I/O-circuit GND pads 107b.

To the signal pads 103, input/output circuits 104 are coupled to be electrically coupled to the internal circuits formed in the internal circuit region 101 via the input/output circuits 104. In other words, circuits serving as interfaces between the internal circuits and external circuits located outside the semiconductor chip 100 are the input/output circuits 104 and the signal pads 103 as terminals are coupled to the input/output circuits 104.

To the internal-circuit power source pads 105a, power source voltages Vdd for driving the internal circuits are applied. Wires are formed from the internal-circuit power source pads 105a to the internal circuits to supply the power source voltages Vdd to the internal circuits. Likewise, reference potentials (ground potentials) Vss are applied to the internal-circuit GND pads 105b. Wires are formed from the internal-circuit GND pads 105b to the internal circuits to supply the reference potentials Vss to the internal circuits.

To the I/O-circuit power source pads 107a, power source voltages Vccq for driving the input/output circuits 104 are applied. Likewise, to the I/O-circuit GND pads 107b, reference potentials Vssq are applied.

Thus, the semiconductor chip 100 has the signal pads 103, the internal-circuit power source pads 105a, the internal-circuit GND pads 105b, the I/O-circuit power source pads 107a, and the I/O-circuit GND pads 107b. During the transportation of the semiconductor chip, these pads may come in contact with a human body and cause ESD (Electro Static Discharge). For example, when any of the internal-circuit power source pads 105a for supplying the power source potential Vdd to the internal circuits causes the ESD, a surge current flows in the internal circuit coupled to the internal-circuit power source pad 105a to break down an element (MISFET (Metal Insulator Semiconductor Field Effect Transistor) or the like) composing the internal circuit.

To protect the internal circuits from the surge current resulting from electrostatic discharge, electrostatic protection circuits 106 are provided between the internal-circuit power source pads 105a and the internal-circuit GND pads 105b. Likewise, to protect the input/output circuits 104 from the surge current resulting from electrostatic discharge, electrostatic protection circuits 108 are provided between the I/O-circuit power source pads 107a and the I/O-circuit GND pads 107b, and electrostatic protection circuits are also provided in the input/output circuits 104. These electrostatic protection circuits are normally formed in the I/O region.

The protection of the internal circuits by the electrostatic protection circuits will be described by using, as an example, the case where a surge current is applied to any of the internal-circuit power source pads 105a. FIG. 15 is a view showing the protection of the internal circuits when the surge voltage is applied to the internal-circuit power source pad 105a. As shown in FIG. 15, the internal circuit composed of, e.g., CMISFETs (Complementary MISFETs) is formed in the core region 101, and the power source potential Vdd and the reference potential Vss are supplied thereto. On the other hand, the wires for supplying the power source voltage Vdd and the reference potential Vss to the internal circuit are provided to extend to the I/O region 102. In the I/O region, the wire for supplying the power source potential Vdd is coupled to the internal-circuit power source pad 105a. Likewise, in the I/O region, the wire for supplying the reference potential Vss is coupled to the internal-circuit GND pad 105b. In the I/O region, the electrostatic protection circuit 106 is formed between the internal-circuit power source pad 105a and the internal-circuit GND pad 105b.

It is assumed herein that the surge voltage resulting from electrostatic discharge is applied to the internal-circuit power source pad 105a. In response to this, the electrostatic protection circuit 106 operates so that the surge current flows therein. By thus causing the surge current to flow in the electrostatic protection circuit 106, it is possible to prevent the surge current from flowing in the internal circuit formed in the core region 101. Therefore, it will be understood that the internal circuit can be protected from electrostatic discharge by providing the electrostatic protection circuit 106.

In recent years, size reduction of a semiconductor chip has been carried out and, in particular, the miniaturization of internal circuits formed in the semiconductor chip has been promoted. On the other hand, a SOC product and a product forming a microcomputer, in particular, have increased in performance and multi-functionality. Accordingly, the number of bonding pads formed in the semiconductor chip has increased. This has caused the problem that, even though the internal circuits are miniaturized to reduce the size of the semiconductor chip, the size reduction of the semiconductor chip cannot be achieved. That is, even though the internal circuits are miniaturized, the number of the bonding pads formed in the peripheral portion of the semiconductor chip is increased, so that the situation is encountered in which the size of the semiconductor chip is primarily determined by the bonding pads and the I/O circuits formed in the I/O region.

In view of the situation, a technology which forms the bonding pads formed in the I/O region also in the core region (internal circuit region) has been examined. FIG. 16 is a view showing an example in which pads formed in a semiconductor chip 110 are formed not only in the I/O region 102 but also in the core region 101. As shown in FIG. 16, the internal-circuit power source pads 105a and the internal-circuit GND pads 105b are formed on the core region 101. In addition, some of the signal pads 103, the I/O-circuit power source pads 107a, and the I/O-circuit GND pads 107b are also formed on the core region 101. Accordingly, it is possible to reduce the number of the pads formed in the I/O region 102 and thereby facilitate the size reduction of the semiconductor chip 110.

When attention is focused herein on the internal-circuit power source pads 105a and the internal-circuit GND pads 105b, the electrostatic protection circuits 106 coupled to the internal-circuit power source pads 105a and to the internal-circuit GND pads 105b are formed in the I/O region 102. Thus, in the structure of the semiconductor chip 110 shown in FIG. 16, the internal-circuit power source pads 105a and the internal-circuit GND pads 105b are formed in the core region 101, while the electrostatic protection circuits 106 are formed in the I/O region 102. In this case, when a surge voltage resulting from electrostatic discharge is applied to any of the internal-circuit power source pads 105a, the problem occurs that the corresponding internal circuit may not be protected sufficiently.

A description will be given hereinbelow to the problem. FIG. 17 is a view showing the application of the surge voltage to the internal-circuit power source pad 105a when the internal-circuit power source pad 105a and the internal-circuit GND pad 105b are placed in the core region 101 and the electrostatic protection circuit 106 is placed in the I/O region 102.

As shown in FIG. 17, when the surge voltage is applied to the internal-circuit power source pad 105a, the possibility occurs that the internal circuit immediately underlying the internal-circuit power source pad 105a is lower in resistance and more likely to be coupled between the internal-circuit power source pad 105a and the internal-circuit GND pad 105b than the electrostatic protection circuit 106 placed on the I/O region 102. That is, because the internal-circuit power source pad 105a and the internal circuit are formed in the same core region 101, the wiring distance therebetween is shorter. By contrast, the internal-circuit power source pad 105a is formed in the core region 101 and the electrostatic protection circuit 106 is formed in the I/O region 102, so that the wiring distance therebetween or the wire coupling the internal-circuit power source pad 105a to the electrostatic protection circuit 106 is longer. As a result, there may be a case where a path extending from the internal-circuit power source pad 105a to the internal-circuit GND pad 105b via the internal circuit is lower in resistance than a path extending from the internal-circuit power source pad 105a to the internal-circuit GND pad 105b via the electrostatic protection circuit 106. Because a surge current flows along a lower-resistance path, the surge current then flows in the internal circuit to cause the possibility of breakdown of the internal circuit. In other words, the situation may occur in which, even though the electrostatic protection circuit 106 is provided, the internal circuit cannot be protected sufficiently.

An object of the present invention is to provide a technology which allows sufficient protection of internal circuits from electrostatic discharge even when internal-circuit power source pads and internal-circuit GND pads are formed on an internal circuit region.

The above and other objects and novel features of the present invention will become apparent from the description of the present specification and the accompanying drawings.

As shown below, a brief description will be given to the outline of the representative aspects of the present invention disclosed in the present application. An embodiment of the present invention relates to a semiconductor device comprising a semiconductor chip having: (a) an I/O region in which an input/output circuit serving as an interface with an external circuit is formed; and (b) an internal circuit region which is other than the I/O region and in which an internal circuit is formed, wherein an internal-circuit power source pad for supplying a source power to the internal circuit is formed on the internal circuit region. To the internal-circuit power source pad, an electrostatic protection circuit is coupled, and a circuit composing part of the electrostatic protection circuit is formed in the internal circuit region.

The following is the brief description of effects achievable by the representative aspects of the invention disclosed in the present application. According to the embodiment, the discharge circuit composing part of the electrostatic protection circuit is formed in the internal circuit region. Therefore, even when the internal-circuit power source pad and the internal-circuit GND pad are placed in the internal circuit region, not in the I/O region, the internal circuit can be sufficiently protected from electrostatic discharge.

### BRIEF DESCRIPTION OF THE DRAWINGS

FIG. 1 is a view showing the layout of a semiconductor chip in an embodiment of the present invention;

FIG. 2 is a view showing an electrostatic protection circuit in the embodiment;

FIGS. 3A to 3D are graphs showing time-varying changes in voltage or surge current in the individual portions of the electrostatic protection circuit shown in FIG. 2;

FIG. 4 is a view showing a discharge circuit composing the electrostatic protection circuit which is formed in a core region;

FIG. 5 is a circuit diagram showing an example of the discharge circuit;

FIG. 6 is a circuit diagram showing another example of the discharge circuit;

FIG. 7 is a circuit diagram showing an example of a control circuit;

FIG. 8 is a circuit diagram showing another example of the control circuit;

FIG. 9 is a circuit diagram showing a NAND circuit as an example of an internal circuit;

FIG. 10 is a view showing the layout of the NAND circuit;

FIG. 11 is a view showing an example of the layout of the discharge circuit;

FIG. 12 is a view showing another example of the layout of the discharge circuit;

FIG. 13 is a view showing still another example of the layout of the discharge circuit;

FIG. 14 is a view showing the layout of a semiconductor chip, which is examined by the present inventors;

FIG. 15 is a view showing a surge current flowing in an electrostatic protection circuit;

FIG. 16 is a view showing the layout of another semiconductor chip, which is examined by the present inventors; and

FIG. 17 is a view showing a surge current flowing in an electrostatic protection circuit.

### DETAILED DESCRIPTION OF THE PREFERRED EMBODIMENTS

A description will be given herein below to the present invention by dividing it, if necessary, into a plurality of sections or embodiments for the sake of convenience. However, they are by no means irrelevant to each other unless shown particularly explicitly and are mutually related to each other such that one of the sections or embodiments is a variation or a detailed or complementary description of some or all of the others.

If the number and the like of elements (including the number, numerical value, amount, and range thereof) are referred to in the following embodiments, they are not limited to specific numbers unless shown particularly explicitly or unless they are obviously limited to specific numbers in principle. The number and the like of the elements may be not less than or not more than specific numbers.

It will easily be appreciated that, in the following embodiments, the components thereof (including also elements and steps) are not necessarily indispensable unless shown particularly explicitly or unless the components are considered to be obviously indispensable in principle.

Likewise, if the configurations, positional relationship, and the like of the components are referred to in the following embodiments, the configurations and the like are assumed to include those substantially proximate or similar thereto unless shown particularly explicitly or unless obviously they are not in principle. The same shall apply to the foregoing numeric values and the range.

Throughout the drawings for illustrating the embodiments of the present invention, the same parts are designated by the same reference numerals in principle and the repeated description thereof will be omitted. There are cases where even plan views may be hatched for easy viewing of the drawings.

Referring to the drawings, a semiconductor device in the first embodiment of the present invention will be described. As the semiconductor device in the first embodiment, a semiconductor device termed, e.g., a SOC (System On Chip) will be described as an example.

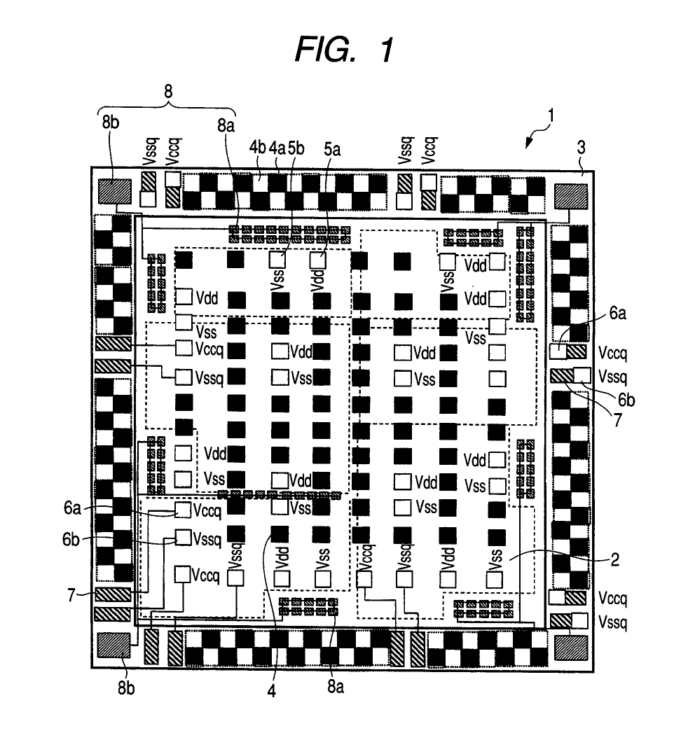

FIG. 1 is a plan view obtained when a semiconductor chip 1 in the present embodiment is viewed from above the upper surface thereof. In FIG. 1, the semiconductor chip 1 has a rectangular shape. In the center region of the semiconductor chip 1, a core region (internal circuit region) 2 is formed. In the core region 2, internal circuits composed of, e.g., MISFETs (Metal Insulator Semiconductor Field Effect Transistors) are formed. Specifically, a system composed of logic circuits as the internal circuits, a microcomputer, a memory, and the like is formed. That is, the semiconductor chip 1 forms a product termed the SOC and the system constituting the SOC is formed in the core region 2 of the semiconductor chip 1. In the peripheral portion of the semiconductor chip 1 located outside the core region 2, an I/O region 3 is formed.

In the semiconductor chip 1, pads which are coupling terminals for coupling to external circuits located outside the semiconductor chip 1 are normally formed. The pads include types of pads such as a signal pad, an I/O-circuit power source pad, an I/O-circuit GND pad, an internal-circuit power source pad, and an internal-circuit GND pad. Normally, these pads are formed in the I/O region 3. In the semiconductor chip 1 in the first embodiment, however, not all of the pads are formed in the I/O region 3 and some of the pads are formed also in the core region 2. The first embodiment presumes the semiconductor chip 1 in which the pads are thus placed. A description will be given hereinbelow to the positions at which the signal pad, the I/O-circuit power source pad, the I/O circuit GND pad, the internal-circuit power source pad, and the internal-circuit GND pad are placed.

The description will be given first to the position at which the signal pad is placed. As shown in FIG. 1, signal pads 4a and input/output circuits (I/O circuits) 4b are formed in the I/O region 3. To the signal pads 4a, the input/output circuits 4b are coupled so that the signal pads 4a are electrically coupled to the internal circuits formed in the core region 2 via the input/output circuits 4b. In other words, circuits serving as interfaces between the internal circuits and the external circuits located outside the semiconductor chip 1 are the input/output circuits 4b and the signal pads 4a as terminals are coupled to the input/output circuits 4b. In the I/O region 3, the signal pads 4a are arranged in, e.g., a staggered pattern to increase the integration density. It is to be noted herein that not all of the signal pads 4a are formed in the I/O region 3 and some of the signal pads 4a are formed also in the core region 2.

Next, the description will be given to the respective positions at which the internal-circuit power source pad and the internal-circuit GND pad are placed. As shown in FIG. 1, internal-circuit power source pads 5a and internal-circuit GND pads 5b are not formed in the I/O region 3 and are formed in the core region 2. To the internal-circuit power source pads 5a, power source voltages Vdd for driving the internal circuits are applied. Wires are formed from the internal-circuit power source pads 5a to the internal circuits to supply the power source voltages Vdd to the internal circuits. Likewise, reference potentials (ground potentials) Vss are applied to the internal-circuit GND pads 5b. Wires are formed from the internal-circuit GND pads 5b to the internal circuits to supply the reference potentials Vss to the internal circuits. Thus, the internal-circuit power source pads 5a and the internal-circuit GND pads 5b have the function of supplying potentials to the internal circuits formed in the core region 2 and, by placing these pads in the core region 2, it is possible to reduce potential fluctuations and supply the potentials with reduced fluctuations to the internal circuits.

Subsequently, the description will be given to the respective positions at which the I/O-circuit power source pad and the I/O circuit GND pad are placed. As shown in FIG. 1, I/O-circuit power source pads 6a and I/O-circuit GND pads 6b are placed in both of the I/O region 3 and the core region 2. To the I/O-circuit power source pads 6a, power source voltages Vccq for driving the input/output circuits 4b are applied. Likewise, to the I/O-circuit GND pads 6b, reference potentials Vssq are applied.

As described above, in the semiconductor chip 1 in the first embodiment, not all of the pads are formed in the I/O region 3 and some of the pads are formed also in the core region 2. An advantage offered by thus placing the pads also in the core region 2 will be described.

Normally, the pads such as the signal pads, the I/O-circuit power source pads, the I/O-circuit GND pads, the internal-circuit power source pads, and the internal-circuit GND pads are all formed in the I/O region.

However, in recent years, the size reduction of a semiconductor chip has been carried out and, in particular, the miniaturization of internal circuits formed in the semiconductor chip has been promoted. On the other hand, a SOC product and a product forming a microcomputer, in particular, have increased in performance and multi-functionality. Accordingly, the number of pads formed in the semiconductor chip has increased. This has caused the problem that, even though the internal circuits are miniaturized to reduce the size of the semiconductor chip, the size reduction of the semiconductor chip cannot be achieved. That is, even though the internal circuits are miniaturized, the number of the pads formed in the peripheral portion of the semiconductor chip is increased, so that the situation is encountered in which the size of the semiconductor chip is primarily determined by the pads and the I/O circuits formed in the I/O region.

In view of the situation, it is performed to form the pads formed in the I/O region also on the core region (internal circuit region). With the technology, even when the SOC product or the like has increased in performance and multi-functionality and the number of pads is increased, the advantage of allowing a reduction in the size of the semiconductor chip is offered. To the semiconductor chip 1 in the first embodiment also, the structure in which the pads are placed not only in the I/O region 3 but also in the core region 2 is adopted as a premise.

Thus, the pads are formed in the semiconductor chip 1. However, during the transportation of the semiconductor chip 1, the pads may come in contact with a human body and cause ESD (Electro Static Discharge). For example, when any of the internal-circuit power source pads 5a for supplying the power source potential Vdd to the internal circuits causes electrostatic discharge, a surge current flows in the internal circuit coupled to the internal-circuit power source pad 5a to break down an element (MISFET or the like) composing the internal circuit.

To protect the internal circuits from the surge current resulting from electrostatic discharge, electrostatic protection circuits 8 are provided between the internal-circuit power source pads 5a and the internal-circuit GND pads 5b, as shown in FIG. 1. Likewise, to protect the input/output circuits 4b from the surge current resulting from electrostatic discharge, electrostatic protection circuits 7 are provided between the I/O-circuit power source pads 6a and the I/O-circuit GND pads 6b. Furthermore, because the surge voltage resulting from electrostatic discharge may also be applied to the signal pads 4a, electrostatic protection circuits are provided also in the input/output circuits 4b coupled to the signal pads 4a.

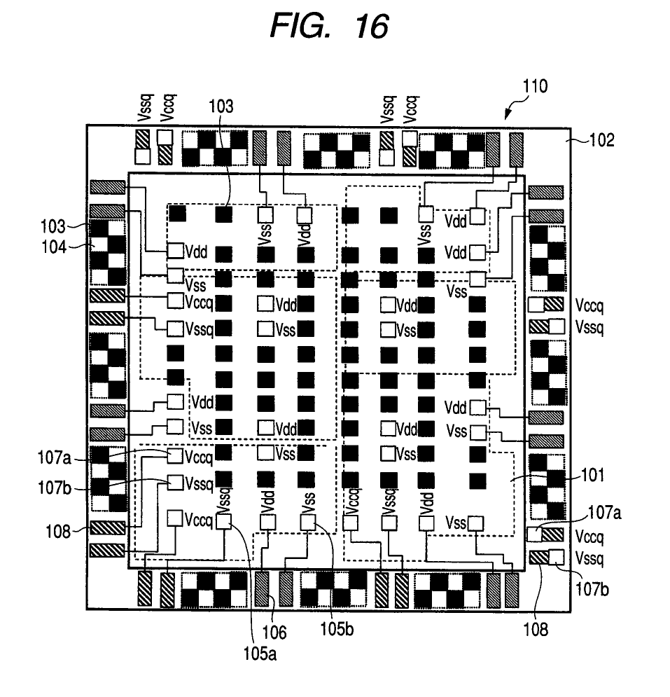

As shown in FIG. 16, these electrostatic protection circuits are normally formed in the I/O region. In this case, when attention is focused on the internal-circuit power source pads 105a and the internal circuits GND pads 105b, the electrostatic protection circuits 106 coupled to the internal-circuit power source pads 105a and to the internal circuits GND pads 105b are also formed in the I/O region 102. Thus, in the structure of the semiconductor chip 110 shown in FIG. 16, the internal-circuit power source pads 105a and the internal-circuit GND pads 105b are formed in the core region 101, while the electrostatic protection circuits 106 are formed in the I/O region 102. In this case, when the surge voltage resulting from electrostatic discharge is applied to any of the internal-circuit power source pads 105a, the problem occurs that the corresponding internal circuit may not be protected sufficiently.

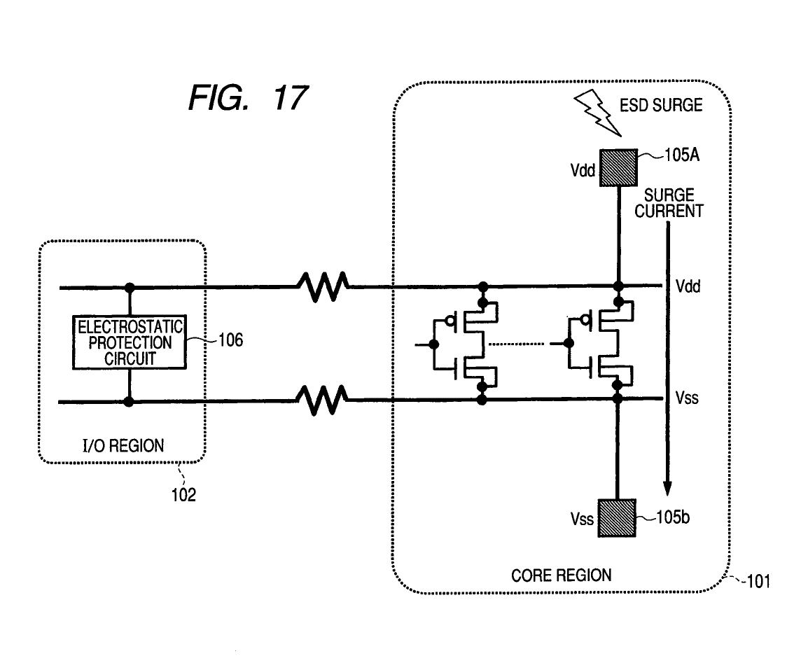

A description will be given to the problem. FIG. 17 is a view showing the application of the surge voltage to the internal-circuit power source pad 105a when the internal-circuit power source pad 105a and the internal-circuit GND pad 105b are placed in the core region 101 and the electrostatic protection circuit 106 is placed in the I/O region 102.

As shown in FIG. 17, when the surge voltage is applied to the internal-circuit power source pad 105a, the possibility occurs that the internal circuit immediately underlying the internal-circuit power source pad 105a is lower in resistance and more likely to be coupled between the internal-circuit power source pad 105a and the internal-circuit GND pad 105b than the electrostatic protection circuit 106 placed on the I/O region 102. That is, because the internal-circuit power source pad 105a and the internal circuit are formed in the same core region 101, the wiring distance therebetween is shorter. By contrast, the internal-circuit power source pad 105a is formed in the core region 101 and the electrostatic protection circuit 106 is formed in the I/O region 102, so that the wiring distance or the wire coupling the internal-circuit power source pad 105a to the electrostatic protection circuit 106 is longer. As a result, there may be a case where the path extending from the internal-circuit power source pad 105a to the internal-circuit GND pad 105b via the internal circuit is lower in resistance than the path extending from the internal-circuit power source pad 105 to the internal-circuit GND pad 105b via the electrostatic protection circuit 106. Because a surge current flows along a lower-resistance path, the surge current then flows in the internal circuit to cause the possibility of breakdown of the internal circuit. In other words, the situation may occur in which, even though the electrostatic protection circuit 106 is provided, the internal circuit cannot be protected sufficiently.

The problem becomes obvious when the internal-circuit power source pad 105a and the internal-circuit GND pad 105b are placed in the core region 101 and the electrostatic protection circuit 106 is placed in the I/O region 102.

By contrast, when the I/O-circuit power source pad 107a and the I/O-circuit GND pad 107b are placed in the core region 101 and the electrostatic protection circuit 108 is placed in the I/O region 102, there is no problem. This is because the I/O-circuit power source pad 107a and the I/O-circuit GND pad 107b are for supplying the potentials to the input/output circuit 104 formed in the I/O region 102. In other words, this is because a main object to be protected from the surge voltage inputted to the I/O-circuit power source pad 107a is the input/output circuit 104 coupled to the I/O-circuit power source pad 107a, and the input/output circuit 104 is formed in the I/O region 102. Therefore, by placing the electrostatic protection circuit 108 in the I/O region 102 in which the input/output circuit 104 as the object to be protected is placed, the input/output circuit 104 can be sufficiently protected from electrostatic discharge.

In the case where the signal pad 103 is placed in the core region 101 and the electrostatic protection circuit is provided in the input/output circuit 104 formed in the I/O region 102 also, the problem described above is not obvious, for which various reasons can be considered. The signal pad 103 is coupled to the internal circuit via the input/output circuit 104. Accordingly, it is conceived that, when a structure is adopted in which the signal pad 103 is placed in the core region 101 and the electrostatic protection circuit is provided in the input/output circuit 104 formed in the I/O region 102, the wiring distance between the signal pad 103 and the internal circuit is apparently shorter than the wiring distance between the signal pad 103 and the electrostatic protection circuit. Therefore, it is considered that a surge current flows to the internal circuit due to the surge voltage applied to the signal pad 103 and the internal circuit may break down.

In an actual situation, however, it is assumed that a wire is coupled from the signal pad 103 placed in the core region 101 to the input/output circuit 104 placed in the I/O region 102 and then coupled from the input/output circuit 104 formed in the I/O region 102 to the internal circuit formed in the core region 101. That is, it is seen that, unlike with the internal-circuit power source pad 105a, even when the signal pad 103 is placed in the core region 101, the wiring distance between the signal pad 103 and the internal circuit is rather longer than shorter. From this, it can be considered that the problem described above is not obvious even when the signal pad 103 is placed in the core region 101. Even when the signal pad 103 is placed in the core region 101, the input/output circuit 104 is formed between the signal pad 103 and the internal circuit. Therefore, it can be considered that, for protecting the input/output circuit 104 from electrostatic discharge, it is proper to provide the electrostatic protection circuit in the input/output circuit 104 placed in the I/O region 102.

From the foregoing, it will be understood that, when the structure is adopted in which the internal-circuit power source pad 105a and the internal-circuit GND pad 105b are placed in the core region 101 and the electrostatic protection circuit 106 is placed in the I/O region 102, the internal circuit cannot be protected sufficiently from electrostatic discharge. Even though some of the pads are formed in the core region 101, the problem described above occurs when the internal-circuit power source pads 105a and the internal-circuit GND pads 105b are placed in the core region 101. To prevent this, the adoption of a structure is considered in which the internal-circuit power source pad 105a and the internal-circuit GND pad 105b are not included in the pads placed in the core region 101. However, because the internal-circuit power source pad 105a and the internal-circuit GND pad 105b are for supplying the potentials for driving the internal circuit, it is preferable that the internal-circuit power source pad 105a and the internal-circuit GND pad 105b are as close as possible to the internal circuit to which the potentials are supplied. This is because, when the internal-circuit power source pad 105a is at a distance from the internal circuit, e.g., it is susceptible to the influence of a voltage drop or potential fluctuations. In particular, the power source potential for driving the internal circuit has been lowered with the miniaturization of the internal circuit to be more susceptible to the influence of a voltage drop or potential fluctuations. Therefore, when the structure is adopted in which the pads are provided in the core region 101, it is preferable that the internal-circuit power source pad 105a and the internal-circuit GND pad 105b are placed in the core region 101. This leads to the adoption of the structure in which the internal-circuit power source pad 105a and the internal-circuit GND pad 105b are placed in the core region 101 and the electrostatic protection circuit 106 is placed in the I/O region 102. As a result, it becomes obvious that the internal circuit cannot be protected sufficiently from electrostatic discharge.

In view of the foregoing, as shown in FIG. 1, the first embodiment forms a discharge circuit 8a composing part of each of the electrostatic discharge circuits 8 in the core region 2, which is one of the characteristic features of the present embodiment. Each of the electrostatic protection circuits 8 is composed of the discharge circuit 8a for causing a surge current to flow therein and a control circuit 8b for controlling the discharge circuit 8a. By placing the discharge circuit 8a composing part of the electrostatic protection circuit 8 in the core region 2, the internal circuit can be protected sufficiently from an electrostatic discharge.

The reason for this is that, in the case where the internal-circuit power source pad 5a is formed in the core region 2, when the discharge circuit 8a is formed in the core region 2, the wiring distance between the internal-circuit power source pad 5a and the discharge circuit 8a can be shortened. In other words, when the discharge circuit is formed in the I/O region 3, the wiring distance between the internal-circuit power source pad 5a and the discharge circuit is longer. As a result, there may be a case where a path extending from the internal-circuit power source pad 5a to the internal-circuit GND pad 5b via the internal circuit is lower in resistance than a path extending from the internal-circuit power source pad 5a to the internal-circuit GND pad 5b via the discharge circuit. Because a surge current flows along a lower-resistance path, the surge current then flows in the internal circuit to cause the possibility of breakdown of the internal circuit. By contrast, when the discharge circuit 8a is formed in the core region 2 as in the present embodiment, the wiring distance between the internal-circuit power source pad 5a and the discharge circuit 8b is shorter than the case where the discharge circuit 8a is formed in the I/O region 3. Accordingly, the path extending from the internal-circuit power source pad 5a to the internal-circuit GND pad 5b via the discharge circuit 8a is lower in resistance than the path extending from the internal-circuit power source pad 5a to the internal-circuit GND pad 5b via the internal circuit. As a result, even when a surge voltage resulting from electrostatic discharge is applied to the internal-circuit power source pad 5a, the surge current flows in the discharge circuit 8a. Therefore, it is possible to sufficiently protect the internal circuit coupled to the internal-circuit power source pad 5a from electrostatic discharge.

In the present embodiment, the plural discharge circuits 8a formed between the internal-circuit power source pads 5a and the internal-circuit GND pads 5b are provided in parallel. That is, the plural discharge circuits 8a are provided in parallel in the core region 2 in correspondence to one pair of the internal-circuit power source pad 5a and the internal-circuit GND pad 5b. The arrangement is provided considering that the surge current allowed to flow by the single discharge circuit 8a has an upper limit value and, when a large surge current is generated by electrostatic discharge, it becomes difficult to cope with the large surge current with the single discharge circuit 8a. That is, by providing the plural discharge circuits 8a in parallel, it is possible to cope with a larger surge current.

Thus, the plural discharge circuits 8a are formed in the core region 2 such that the single control circuit 8b is provided for the plural discharge circuits 8a, not such that the control circuits 8b for controlling the discharge circuits 8a correspond in number to the discharge circuits 8a on a per one-to-one basis. This is because, unlike the discharge circuit 8a, the control circuit 8b does not directly cause a surge current to flow and it is sufficient for the control circuit 8b to control the plural discharge circuits 8a. As a result, each of the electrostatic protection circuits 8 in the present embodiment is composed of the discharge circuits 8a and the control circuit 8b to provide the structure in which the single control circuit 8b is provided for the plural discharge circuits 8a.

The discharge circuits 8a are formed in the core region 2, while the control circuit 8b is formed in the I/O region 3. That is, in the present embodiment, not the whole electrostatic protection circuit 8 is formed in the core region and only the discharge circuits 8a are formed in the core region 2. By thus providing only the discharge circuits 8a composing part of the electrostatic protection circuit 8 in the core region 2 also, it is possible to sufficiently protect the internal circuit formed in the core region 2. This is because, of the electrostatic protection circuit 8, it is the discharge circuits 8a which actually cause the surge current to flow therein and, by placing the discharge circuits 8a in proximity to the internal circuit, the surge current is caused to flow in the discharge circuits 8a which are lower in resistance than the internal circuit. In other words, the positions at which the discharge circuits 8a are placed are important in protecting the internal circuit. By providing the discharge circuits 8a in the core region 2, the path extending from the internal-circuit power source pad 5a to the internal-circuit GND pad 5b via the discharge circuits 8a becomes lower in resistance and is allowed to serve as a path which reliably causes the surge current to flow therealong.

It can also be considered herein that not only the discharge circuits 8a but also the control circuit 8b is formed in the core region 2. In other words, it can also be considered that the entire electrostatic circuit 8 is provided in the core region 2. However, the control circuit 8b is not provided in the core region 2 in consideration of the point shown below. In the internal circuit formed in the core region 2, MISFETs are formed, but the MISFETS have been miniaturized. On the other hand, MISFETs are also formed in the input/output circuit 4b in the I/O region 3, but the MISFET have not been so miniaturized as the MISFETs formed in the internal circuit. That is, the circuits each composed of the MISFETs are formed respectively in the core region 2 and in the I/O region 3, and the MISFETs formed in the core region 2 are different in size from the MISFETs formed in the I/O region 3. For example, the gate insulating films of the MISFETs formed in the I/O region 3 are thicker than the gate insulating films of the MISFETs formed in the core region 2.

Each of the electrostatic protection circuits 8 is composed of the discharge circuits 8a and the control circuit 8b, and the discharge circuits 8a can be formed using MISFETs each of the same size as the MISFETs forming the internal circuit. By contrast, a capacitor element is used for the control circuit 8b but, when the capacitor element is formed of the gate capacitance of the MISFET, a thick film is required as the gate insulating film of the MISFET. That is, it is required to use the MISFET of the same size as each of the MISFETs formed in the I/O region 3 as the MISFET composing the control circuit 8b and, accordingly, the MISFET of the same size as each of the MISFETs forming the internal circuit cannot be used.

When the control circuit 8b is also formed in the core region 2, it follows therefore that the MISFETs of different sizes are formed in the core region 2. In this case, it becomes necessary to provide the core region 2 with regions in which the MISFETs of different sizes are formed so that the conventional layout placement need to be changed. That is, in the core region 2, the internal circuit is formed using a standard cell composed of a p-channel MISFET and an n-channel MISFET, but the necessity occurs to form MISFETs which cannot be formed using the standard cell. This causes the probability of a situation in which the fabrication process steps are complicated and the accuracy of patterning in the core region 2 is degraded thereby. For example, in the patterning in the core region 2, the necessity occurs to form the MISFETs of different sizes but, when the MISFETs of different sizes are simultaneously patterned for the avoidance of complication of the fabrication process steps, a problem is likely to occur in the accuracy of the miniaturized standard cell.

From such viewpoints, the control circuit 8b composing part of each of the electrostatic protection circuits 8 is placed in the I/O region 3, not in the core region 2. This allows the solution of the problem resulting from the placement of the control circuit 8b in the core region 2. That is, it is unnecessary to form the MISFETs of different sizes in the core region 2 and significantly change the layout placement. In addition, it is also possible to suppress the complication of the fabrication process steps and the accuracy degradation of a photolithographic technology.

In the present embodiment, the effect of reliably preventing the breakdown of the internal circuit due to electrostatic discharge can be obtained by providing the discharge circuits 8a in the core region 2, and the effect of allowing the size reduction of the semiconductor chip 1 can also be obtained by providing the discharge circuits 8a in the core region 2. This is because, in contrast to the conventional structure in which the discharge circuits 8a are also formed in the I/O region 3, the discharge circuits 8a are formed in the core region 2 in the present embodiment. Accordingly, the elements formed in the I/O region 3 can be reduced. This allows the size reduction of the I/O region 3 and thereby allows the size reduction of the semiconductor chip 1.

In addition, even when the control circuit 8b is provided in the I/O region 3, the effect of avoiding an increase in the size of the I/O region 3 can be obtained by placing the control circuit 8b, which is placed in the I/O region 3, at the corner portion of the semiconductor chip 1. In other words, although the corner portion of the semiconductor chip 1 has been conventionally a dead space where no element is placed, by placing the control circuit 8b in the dead space, it is possible to place the control circuit 8b in the I/O region 3 without increasing the area of the I/O region 3.

In the structure in which the discharge circuits 8a are placed in the I/O region 3, it is difficult to provide a large number of the discharge circuits 8a between one pair of the internal-circuit power source pad 5a and the internal-circuit GND pad 5b in terms of reducing the elements placed in the I/O region 3. By contrast, in the present embodiment, the discharge circuits 8a are provided in the core region 2 so that, even when a large number of the discharge circuits 8a are provided in parallel between one pair of the internal-circuit power source pad 5a and the internal-circuit GND pad 5b, the size of the I/O region 3 is not increased. Thus, according to the present embodiment, the plural discharge circuits 8a can be provided in parallel, while the size of the semiconductor chip 1 is reduced. As a result, the present embodiment can cope with even a larger surge current.

The discharge circuits 8a are provided in the core region 2 but, when a vacant region is present in the peripheral portion of the core region 2, e.g., the discharge circuits 8a are placed in the vacant region. By forming the discharge circuits 8a in the vacant region, it is possible to place the discharge circuits 8a in the core region 2 without changing the layout of the internal circuit. For example, as the peripheral portion of the core region 2, a region outside the internal-circuit power source pad 5a and the internal-circuit GND pad 5b formed in the core region 2 can be used. The discharge circuits 8a may be formed not only in the peripheral portion of the core region 2, but also in a vacant region in the internal circuit such as, e.g., the vacant region immediately under a power source wire. Briefly, the discharge circuits 8a can be placed not only in the peripheral portion of the core region 2, but also in any vacant space without changing the layout of the internal circuit, provided that the internal circuit is not formed therein.

The semiconductor device in the present embodiment has a structure as described above. Next, a description will be given to a specific structure of each of the electrostatic protection circuits 8.

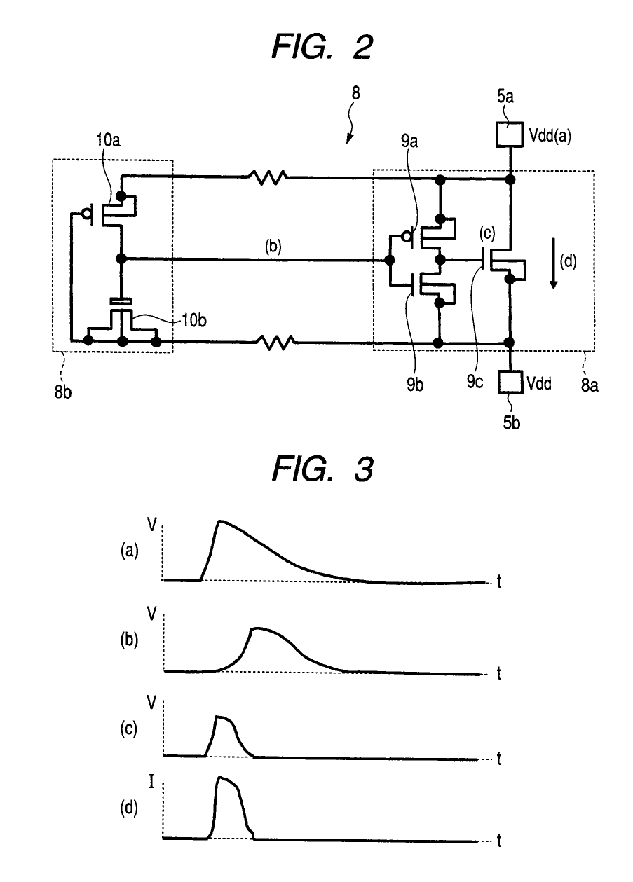

FIG. 2 is a circuit diagram showing an example of the structure of each of the electrostatic protection circuits 8 in the present embodiment. As shown in FIG. 2, the electrostatic protection circuit 8 in the present embodiment is provided between the internal-circuit power source pad 5a and the internal-circuit GND pad 5b. Each of the electrostatic protection circuits 8 is composed of the discharge circuit 8a and the control circuit 8b.

The discharge circuit 8a has the function of directly causing a surge current to flow therein. To implement the function, the discharge circuit 8a is composed of an inverter composed of a CMISFET and an n-channel MISFET. The inverter is composed of a p-channel MISFET 9a formed on the High side and an n-channel MISFET 9b formed on the Low side. To the inverter, an input signal is inputted from the input terminal coupled to the gate electrode of the p-channel MISFET 9a and to the gate electrode of the n-channel MOSFET 9b. The inverter outputs an output signal from the coupling portion between the p-channel MISFET 9a and the n-channel MISFET 9b. With the inverter thus constructed, when a “Hi” input signal is inputted thereto, a “Lo” output signal is outputted therefrom and, when a “Lo” input signal is inputted thereto, a “Hi” output signal is outputted therefrom.

The output of the inverter is inputted to the gate electrode of an n-channel MISFET 9c formed in the subsequent stage such that the ON/OFF state of the n-channel MISFET 9c is controlled by the output of the inverter. The source region and drain region of the n-channel MISFET 9c are connected respectively to the internal-circuit GND pad 5b and to the internal-circuit power source pad 5a. Specifically, a surge current is caused to flow between the drain region and source region of the n-channel MISFET 9c.

Subsequently, the control circuit 8b has the function of controlling the discharge circuit 8a. To implement the function, the control circuit 8b has a p-channel MISFET 10a and a MISFET 10b. The p-channel MISFET 10a is provided to function as a resistor element, not as a transistor. That is, a reference potential (GND) is applied to the gate electrode of the p-channel MISFET 10a so that the p-channel MISFET 10a is in a normally ON state. The p-channel MISFET 10a is coupled between the internal-circuit power source pad 5a for supplying the power source potential and the gate electrode of the MISFET 10b. With the p-channel MISFET 10a thus constructed, an ON-state resistance generated when a current flows is used as the resistance value of the resistor element.

The MISFET 10b is provided to function as a capacitor element, not as a transistor. To implement the function as the capacitor element with the MISFET 10b, the MISFET 10b is coupled between the internal-circuit GND pad 5b and the gate electrode of the p-channel MISFET 10a. The MISFET 10b retains the normally ON state to be used in a state where the source region and the drain region are conducting. As a result, the internal-circuit GND pad 5b and the gate electrode of the p-channel MISFET 10a are brought into a state where they are normally connected via the MISFET 10b so that the reference potential is supplied to the gate electrode of the p-channel MISEFET 10a. In this manner, the capacitor element using a gate insulating film as a capacitor insulating film and using a gate electrode and a substrate (source region and drain region) as electrodes is formed. In the control circuit 8b thus constructed, an output signal is outputted from between the p-channel MISFET 10a and the MISFET 10b and inputted to the input terminal of the discharge circuit 8a.

The electrostatic protection circuit 8 according to the present embodiment is constructed as described above. A description will be given herein below to the operation thereof. The electrostatic protection circuit 8 is for protection when a surge voltage resulting from electrostatic discharge is applied between the internal-circuit power source pad 5a and the internal-circuit GND pad 5b. The protection by the electrostatic protection circuit 8 is against the application of a surge voltage resulting from electrostatic discharge to the semiconductor chip 1 which is not operating during transportation or the like.

First, a description will be given to the case where electrostatic discharge does not occur. At this time, since the semiconductor chip 1 is not operating, it follows that the reference potential is applied to the internal-circuit power source pad 5a and to the internal-circuit GND pad 5b. When the reference potential is applied to the internal-circuit power source pad 5a, a “Lo” output signal (at the reference potential) is outputted from the control circuit 8b via the p-channel MISFET 10a (in the normally ON state) of the control circuit 8b. The “Lo” output signal outputted from the control circuit 8b is inputted to the inverter of the discharge circuit 8a. When the “Lo” input signal is inputted to the inverter, the “Lo” signal is applied to the respective gate electrodes of the p-channel MISFET 9a and the n-channel MISFET 9b, each composing the inverter. As a result, the p-channel MISFET 9a is turned ON and the n-channel MISFET 9b is turned OFF. The turning ON of the p-channel MISFET 9a brings into conduction the internal-circuit power source pad 5a and the gate electrode of the n-channel MISFET 9c. However, since the “Lo” signal (at the reference potential) has been applied to the internal-circuit power source pad 5a, the n-channel MISFET 9c is not turned ON so that the internal-circuit power source pad 5a and the internal-circuit GND pad 5b are electrically insulated.

Next, it is assumed that a surge voltage not lower than “Hi” level (power source potential) is applied to the internal-circuit power source pad 5a. As described above, since the internal-circuit power source pad 5a is coupled to the gate electrode of the n-channel MISFET 9c via the p-channel MISFET 9a of the inverter, a “Hi” signal is applied to the gate electrode of the n-channel MISFET 9c immediately after the surge voltage is applied to the internal-circuit power source pad 5a. As a result, the n-channel MISFET 9c is turned ON to bring the internal-circuit power source pad 5a and the internal-circuit GND pad 5b into conduction, so that a surge current flows.

At this time, in the control circuit 8b, the internal-circuit power source pad 5a is coupled to the capacitor element composed of the MISFET 10b via the p-channel MISFET 10a (in the normally ON state). Accordingly, a current flows in the MISFET 10b as the capacitor element via the p-channel MISFET 10a immediately after the surge voltage is applied to the internal-circuit power source pad 5a. Since the current flows in the MISFET 10b as the capacitor element to accumulate charges therein, the potential (output signal) outputted from the control circuit 8b rises. Immediately after the surge voltage is applied to the internal-circuit power source pad 5a, the charges accumulated in the MISFET 10b as the capacitor element are small in quantity. As a result, the potential outputted from the control circuit 8b has not reached the “Hi” level so that the potential outputted from the control circuit 8b is on the “Lo” level. Consequently, the “Lo” signal is still inputted to the discharge circuit 8a. Accordingly, the state where the p-channel MISFET 9a is ON is maintained so that the internal-circuit power source pad 5a and the gate electrode of the n-channel MISFET 9c remain coupled to each other. At this time, since the surge voltage is applied to the internal-circuit power source pad 5a, a potential corresponding to the “Hi” level is supplied to the gate electrode of the n-channel MISFET 9c. As a result, the n-channel MISFET 9c is turned ON and the surge current continues to flow.

Thereafter, when a given period of time has elapsed, sufficient charges are accumulated in the MISFET 10b as the capacitor element so that the potential (output signal) outputted from the control circuit 8b rises to the “Hi” level. As a result, the potential outputted from the control circuit 8b reaches the “Hi” level so that a “Hi” signal is inputted to the discharge circuit 8a. In response to this, the p-channel MISFET 9a in the ON state is turned OFF and the n-channel MISFET 9b in the OFF state is turned ON. Accordingly, the internal-circuit GND pad 5b is coupled to the gate electrode of the n-channel MISFET 9c. Consequently, a “Lo” signal is applied to the gate electrode of the n-channel MISFET 9c to turn OFF the n-channel MISFET 9c. As a result, the internal-circuit power source pad 5a and the internal-circuit GND pad 5b are electrically insulated so that the surge current no more flows.

Thereafter, when the surge voltage is no more applied to the internal-circuit power source pad 5a, the charges accumulated in the MISFET 10b of the control circuit 8b are gradually discharged so that the electrostatic protection circuit 8 returns to the state before the surge current is applied. In this manner, when the surge voltage is applied to the internal-circuit power source pad 5a, the surge current is allowed to flow by the electrostatic protection circuit 8 composed of the discharge circuit 8a and the control circuit 8b.

Hereinbelow, time-varying changes in potential or surge current in the individual portions of the electrostatic protection circuit corresponding to the operation described above are shown. FIGS. 3A to 3D show time-varying changes in potential or surge current in the individual portions corresponding to the points (a) to (d) in FIG. 2. FIG. 3A shows the time-varying changes in potential at the point (a) (internal-circuit power source pad 5a) of FIG. 2. FIG. 3B shows the time-varying changes in potential at the point (b) (output of the control circuit 8b and input of the discharge circuit 8a) of FIG. 2. FIG. 3C shows the time-varying changes in potential at the point (c) (gate electrode of the n-channel MISFET 9c) of FIG. 2. FIG. 3D shows the time-varying changes in the surge current flowing in the n-channel MISFET 9c.

As shown in FIG. 3A, when the surge voltage is applied to the internal-circuit power source pad 5a, the potential rises. Immediately after the potential rises, the potential applied to the gate electrode of the n-channel MISFET 9c rises (see FIG. 3C) and, as shown in FIG. 3D, the surge current flows in the n-channel MISFET 9c. Then, when a given period has elapsed, the potential corresponding to the output of the control circuit 8b and the input of the discharge circuit 8a rises so that the potential applied to the gate electrode of the n-channel MISFET 9c lowers. Accordingly, the surge current no more flows. Thus, it is seen that the potentials and the surge current change.

In the control circuit 8b, the output potential shifts from the “Lo” level to the “Hi” level after the lapse of the given period to prevent the surge current from flowing after the lapse of the given period. At this time, the given period is determined by the resistance value R of the resistor element (p-channel MISFET 10a) composing the control circuit 8b and the capacitance C of the capacitor element (MISFET 10b). Therefore, it is necessary to set the resistance value R and the capacitance C to allow a sufficient surge current to flow. In other words, because the given period mentioned above depends on a time constant (C * R) which is the product of the resistance value R and the capacitance C, it is necessary to set a proper time constant.

For example, when a discharge time resulting from the surge current is assumed to be 100 ns, a time constant of 100 ns or more is required for the control circuit 8b. To set the time constant of the control circuit 8b to 100 ns, by way of example, a value obtained by multiplying the capacitance C by the resistance value R mentioned above is adjusted to 100 ns.

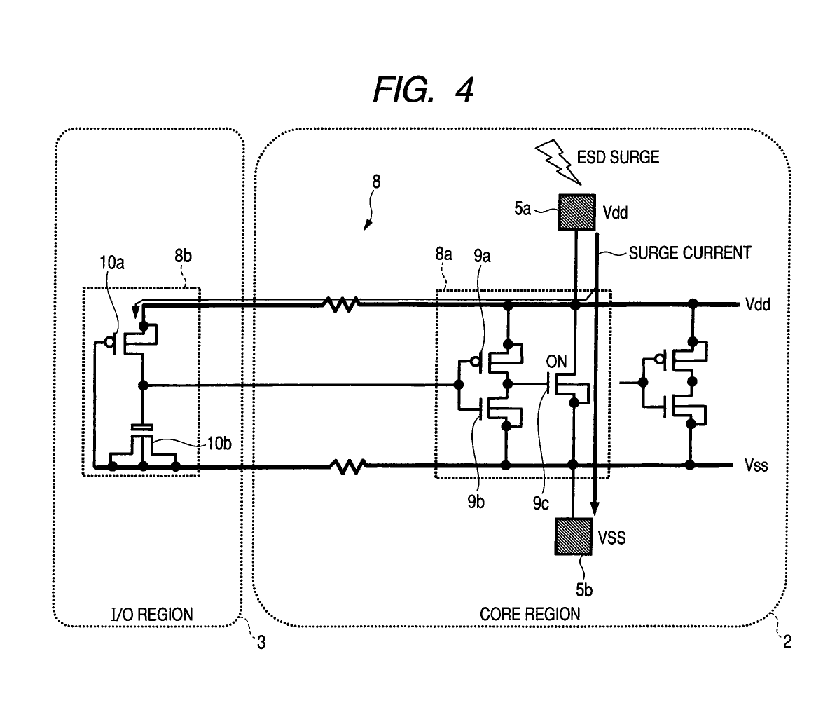

By applying the electrostatic protection circuit 8 described above to the layout shown in FIG. 1, the semiconductor device in the present embodiment is realized. FIG. 4 is a schematic diagram showing the electrostatic protection circuit 8 shown in FIG. 2, of which the discharge circuit 8a is formed in the core region 2 and the control circuit 8b is formed in the I/O region 3. As shown in FIG. 4, the internal-circuit power source pad 5a and the internal-circuit GND pad 5b are formed in the core region 2, and the internal circuit and the discharge circuit 8a are formed between the internal-circuit power source pad 5a and the internal circuit GND pad 5b. As shown in FIG. 2, the discharge circuit 8a is composed of the p-channel MISFET 9a and the n-channel MISFET 9b forming the inverter and the n-channel MISFET 9c formed in the stage subsequent to the inverter.

On the other hand, the control circuit 8b is formed in the I/O region 3. The control circuit 8b is composed of the p-channel MISFET 10a functioning as the resistor element and the MISFET 10b functioning as the capacitor element.

By providing the discharge circuit 8a in the core region 2, the path extending from the internal-circuit power source pad 5a to the internal-circuit GND pad 5b via the discharge circuit 8a (n-channel MISFET 9c) is lower in resistance than the path extending from the internal-circuit power source pad 5a to the internal-circuit GND pad 5b via the internal circuit. In other words, by providing the discharge circuit 8a in the core region 2, the wiring distance between the internal-circuit power source pad 5a and the discharge circuit 8b becomes equal to the wiring distance between the internal-circuit power source pad 5a and the internal circuit. Because the n-channel MISFET 9c of the discharge circuit 8a is ON, the path extending via the discharge circuit 8a is lower in resistance than the path extending via the internal circuit. Accordingly, the surge current flows from the internal-circuit power source pad 5a to the internal-circuit GND pad 5b via the n-channel MISFET 9c of the discharge circuit 8a. As a result, it is possible to sufficiently protect the internal circuit from a surge current resulting from electrostatic discharge.

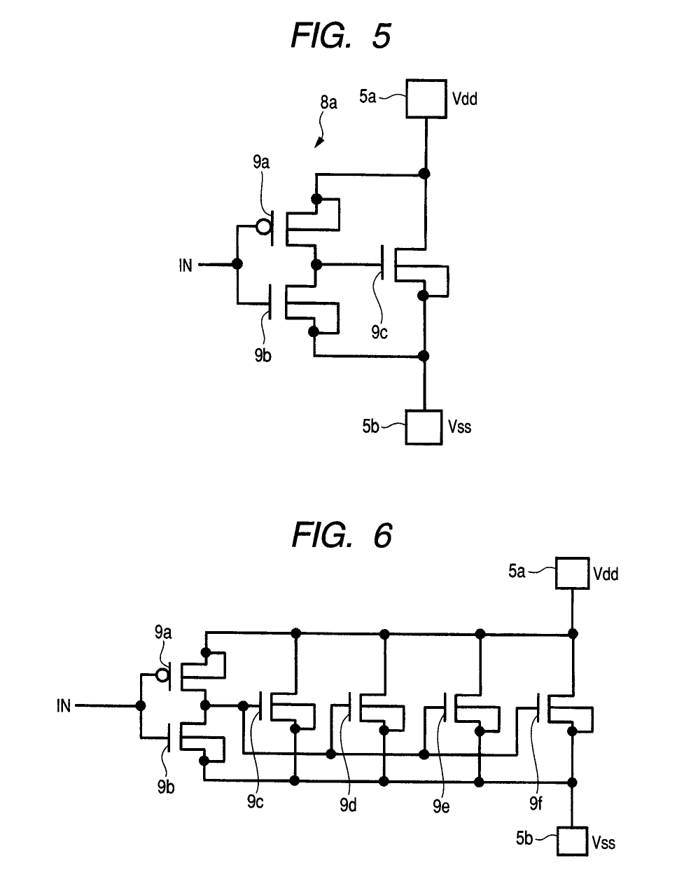

Next, a description will be given to a variation of the discharge circuit 8a. FIG. 5 is a view showing the discharge circuit 8a composing the electrostatic protection circuit 8. As shown in FIG. 5, in the present embodiment, the discharge circuit 8a is composed of the inverter and the n-channel MISFET 9c. When the discharge circuit 8a is thus composed, the surge current flows in the n-channel MISFET 9c. Since the n-channel MISFET 9c formed in the discharge circuit 8a is only one, there is the possibility that, when the surge current becomes large, the large surge current cannot be coped with. To prevent this, a structure is considered in which a plurality of n-channel MISFETs 9c to 9f are provided in parallel as the discharge circuit in the stage subsequent to the inverter, as shown in FIG. 6. By adopting such a structure, the surge current is allowed to flow by the plural n-channel MISFETs 9c to 9f arranged in parallel, and therefore even the large surge current can be coped with.

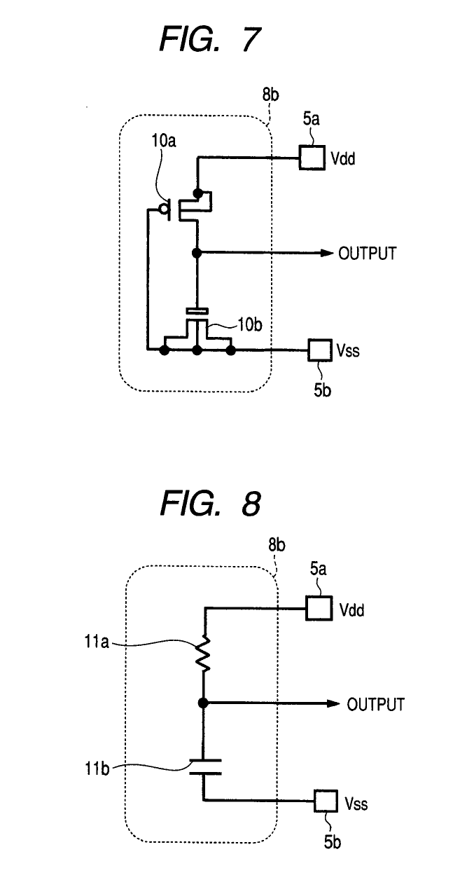

Subsequently, a description will be given to a variation of the control circuit 8b. FIG. 7 is a view showing the control circuit 8b composing the electrostatic protection circuit 8. As shown in FIG. 7, in the present embodiment, the control circuit 8b is composed of the p-channel MISFET 10a and the MISFET 10b. The p-channel MISFET 10a functions as the resistor element and the MISET 10b functions as the capacitor element. Accordingly, the control circuit 8b may also be composed of a resistor element 11a and a capacitor element 11b, as shown in FIG. 8. In this case, a polysilicon resistor composed of a polysilicon film can be used as the resistor element 11a, while an element using a polysilicon film for an electrode or an element using a metal film for an electrode can be used as the capacitor element.

Next, a description will be given to the fact that the discharge circuit 8a formed in the core region 2 can be formed of MISFETs each of the same size as those of the internal circuit formed in the core region 2. That is, the description will be given to the fact that the internal circuit is formed using a standard cell composed of a p-channel MISFET and an n-channel MISFET as a unit element and that the discharge circuit according to the present embodiment can also be formed using the standard cell. Since the discharge circuit in the present embodiment can be formed using the standard cell, the discharge circuit can be formed without changing the layout of the internal circuit. In particular, if the discharge circuit can be formed using MISFETs each of the same size as those of the internal circuit, the effect of allowing suppression of the complication of the fabrication process steps and the accuracy degradation of a photolithographic technology can be obtained.

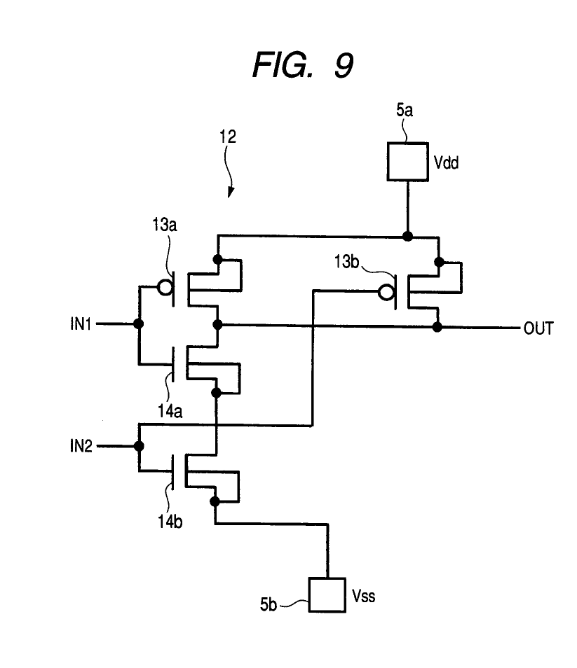

The description will be given first to an example of the internal circuit formed in the core region 2. For example, when a SOC product is formed as the semiconductor chip, a digital circuit such as a NAND circuit, an AND circuit, or an OR circuit is formed as the internal circuit. In FIG. 9, a NAND circuit 12 is shown as an example composing the internal circuit.

As shown in FIG. 9, the NAND circuit 12 is composed of p-channel MISFETs 13a and 13b and n-channel MISFETs 14a and 14b. To the internal-circuit power source pad 5a for supplying a power source potential, the p-channel MISFETs 13a and 13b are connected in parallel, while the n-channel MISFETs 14a and 14b are connected in series to the p-channel MISFET 13a. The n-channel MISFET 14b is further connected to the internal-circuit GND pad 5b for supplying the reference potential. In the NAND circuit 12 thus constructed, an input IN1 is connected to the respective gate electrodes of the p-channel MISEFT 13a and the n-channel MISEFT 14a, while an input IN2 is connected to the respective gate electrodes of the p-channel MISEFT 13b and the n-channel MISFET 14b. To the respective terminals of the p-channel MISFET 13a and 13b which are opposite to the terminals thereof connected to the internal-circuit power source pad 5a, an output OUT is extracted.

For example, when a “Lo” signal (at the reference potential) is inputted to the input IN1 and a “Lo” signal is inputted to the input IN2, the p-channel MISFETs 13a and 13b are turned ON, while the n-channel MISFETs 14a and 14b are turned OFF. As a result, a “Hi” signal (at the power source potential) is outputted to the output OUT. When a “Lo” signal is inputted to the input IN1 and a “Hi” signal is inputted to the input IN2, the p-channel MISFET 13a and the n-channel MISFET 14b are turned ON, while the p-channel MISFET 13b and the n-channel MISFET 14a are turned OFF. As a result, a “Hi” signal is outputted to the output OUT. Likewise, when a “Hi” signal is inputted to the input IN1 and a “Lo” signal is inputted to the input IN2, the p-channel MISFET 13b and the n-channel MISFET 14a are turned ON, while the p-channel MISFET 13a and the n-channel MISFET 14b are turned OFF. As a result, a “Hi” signal is outputted to the output OUT. Further, when a “Hi” signal is inputted to the input IN1 and a “Hi” signal is inputted to the input IN2, the p-channel MISFETs 13a and 13b are turned OFF, while the n-channel MISFETs 14a and 14b are turned ON. As a result, a “Lo” signal is outputted to the output OUT. In this manner, the NAND circuit 12 operates.

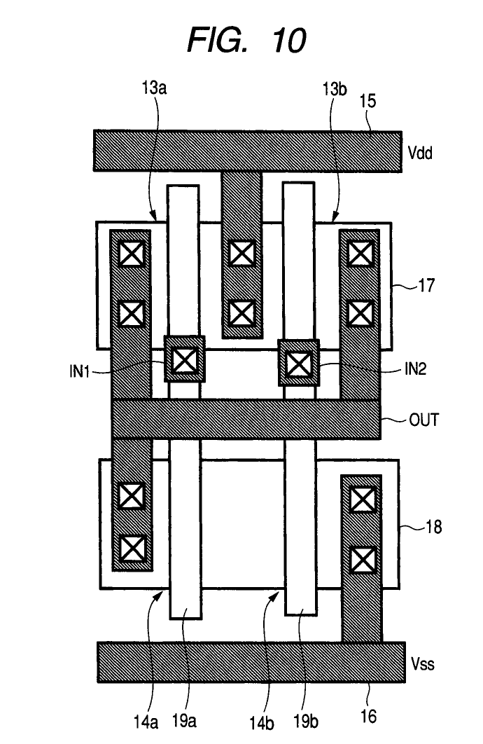

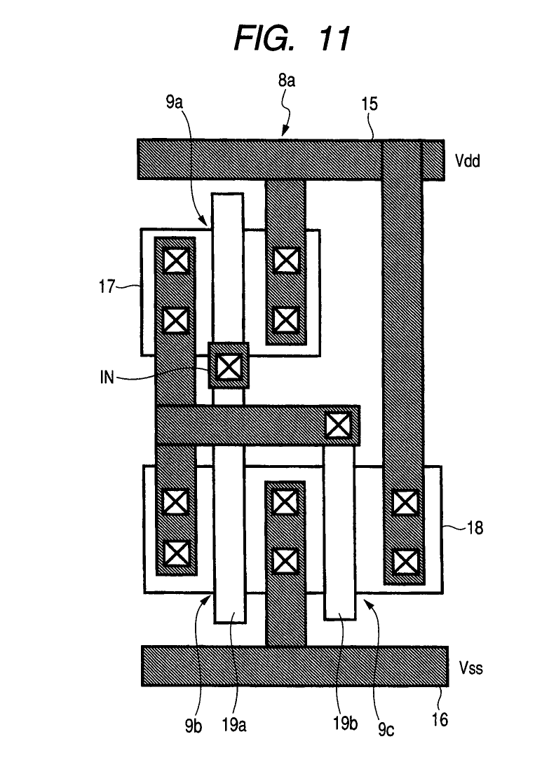

Next, FIG. 10 is a view showing the layout of the NAND circuit 12 formed on the semiconductor chip. As shown in FIG. 10, a power source wire 15 and a GND wire 16 are provided to extend in one direction, while a p-type impurity diffusion region 17 and an n-type impurity diffusion region 18 extending in the one direction are formed between the pair of the power source wire 15 and the GND wire 16. In addition, a plurality of gate electrodes 19a and 19b are formed to intersect the p-type impurity diffusion region 17 and the n-type impurity diffusion region 18 extending in the one direction. In this manner, the p-channel MISFETs 13a and 13b and the n-channel MISFETs 14a and 14b are formed. That is, in FIG. 10, a standard cell composed of the p-channel MISFET 13a and the n-channel MISFET 14a and a standard cell composed of the p-channel MISFET 13b and the n-channel MISFET 14b are formed. By forming the wires by patterning with respect to these standard cells, the NAND circuit 12 shown in FIG. 10 is formed. The other circuits such as the AND circuit and the OR circuit, each composing the internal circuit, are also formed using the standard cells as the reference and, by changing a wiring pattern, a specified circuit is formed. Briefly, the internal circuit forms a different digital circuit by changing the wiring pattern using the standard cells as the layout reference.

In this manner, the internal circuit is formed in the core region 2. Subsequently, a description will be given to an example of the layout of the discharge circuit 8a formed in the core region 2. FIG. 11 is a view showing the layout of the discharge circuit 8a formed in the core region 2. The discharge circuit 8a having the layout structure shown in FIG. 11 is the discharge circuit 8a shown in FIG. 4. As shown in FIG. 11, the power source wire 15 and the GND wire 16 are provided to extend in one direction, while the p-type impurity diffusion region 17 and the n-type impurity diffusion region 18 extending in the one direction are formed between the pair of the power source wire 15 and the GND wire 16. In addition, the plural gate electrodes 19a and 19b are formed to intersect the p-type impurity diffusion region 17 and the n-type impurity diffusion region 18 extending in the one direction. In this manner, the p-channel MISFET 9a and the n-channel MISFET 9b composing the inverter is formed, and the n-channel MISEFT 9c is formed in the stage subsequent to the inverter. Accordingly, it is seen that the discharge circuit 8a is formed by forming the wires by patterning with respect to the standard cell composed of the p-channel MISFET 9a and the n-channel MISFET 9b and the standard cell composed of the n-channel MISFET 9c. From this, it will be understood that the discharge circuit 8a formed in the core region 2 can also be formed in a layout using MISFETs each of the same size as those of the internal circuit. This allows the discharge circuit 8a to be formed without changing the layout of the internal circuit. In particular, since the discharge circuit 8a can be formed of the MISFETs each of the same size as those of the internal circuit, the complication of the fabrication process steps and the accuracy degradation of a photolithographic technology can be suppressed.

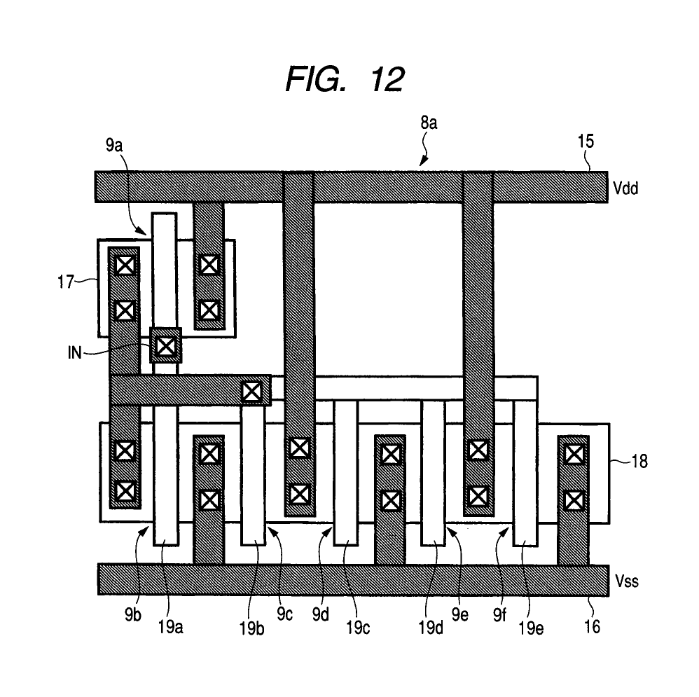

It is further possible to form, by using the standard cells, the discharge circuit 8a in which the plural n-channel MISFETs 9c to 9f are provided as the discharge circuit 8a shown in FIG. 6 in the stage subsequent to the inverter. FIG. 12 is a view showing the layout of the discharge circuit 8a formed in the core region 2. As shown in FIG. 12, the discharge circuit 8a having the layout structure shown in FIG. 12 is the discharge circuit 8a shown in FIG. 6. As shown in FIG. 12, the power source wire 15 and the GND wire 16 are provided to extend in one direction, while the p-type impurity diffusion region 17 and the n-type impurity diffusion region 18 extending in the one direction are formed between the pair of the power source wire 15 and the GND wire 16. In addition, the plural gate electrodes 19a to 19e are formed to intersect the p-type impurity diffusion region 17 and the n-type impurity diffusion region 18 extending in the one direction. In this manner, the p-channel MISFET 9a and the n-channel MISFET 9b composing the inverter is formed, and the n-channel MISFETs 9c to 9f are formed in the stage subsequent to the inverter. Accordingly, it is seen that the discharge circuit 8a is formed by forming the wires by patterning with respect to the standard cell composed of the p-channel MISFET 9a and the n-channel MISFET 9b and respective standard cells composing the n-channel MISFETs 9c to 9f. From this, it will be understood that the discharge circuit 8a formed in the core region 2 can also be formed in a layout using MISFETs each of the same size as those of the internal circuit.

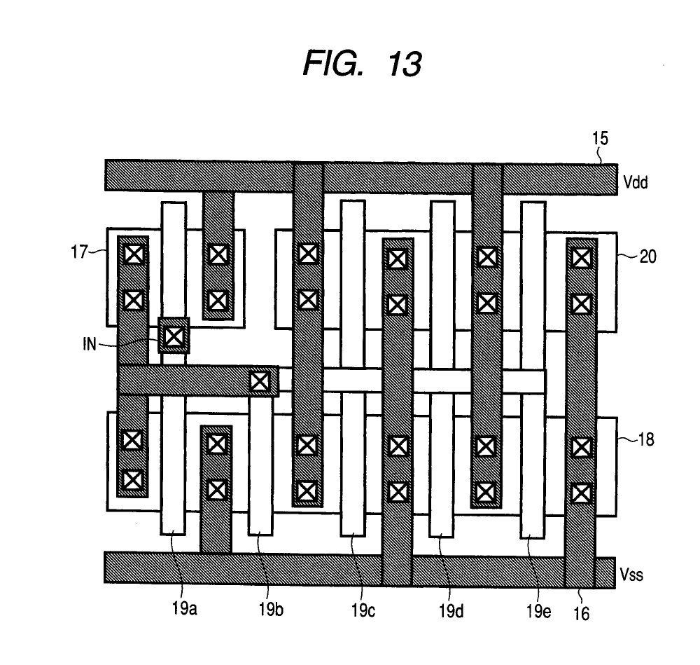

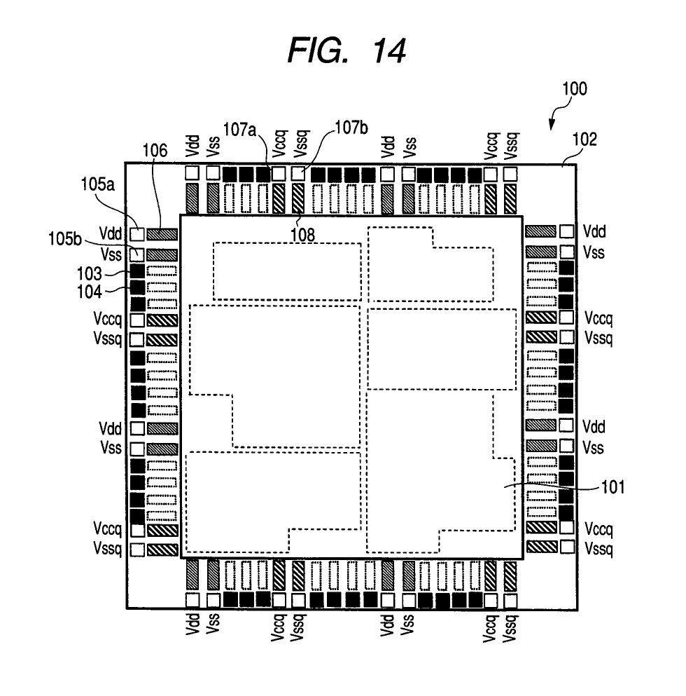

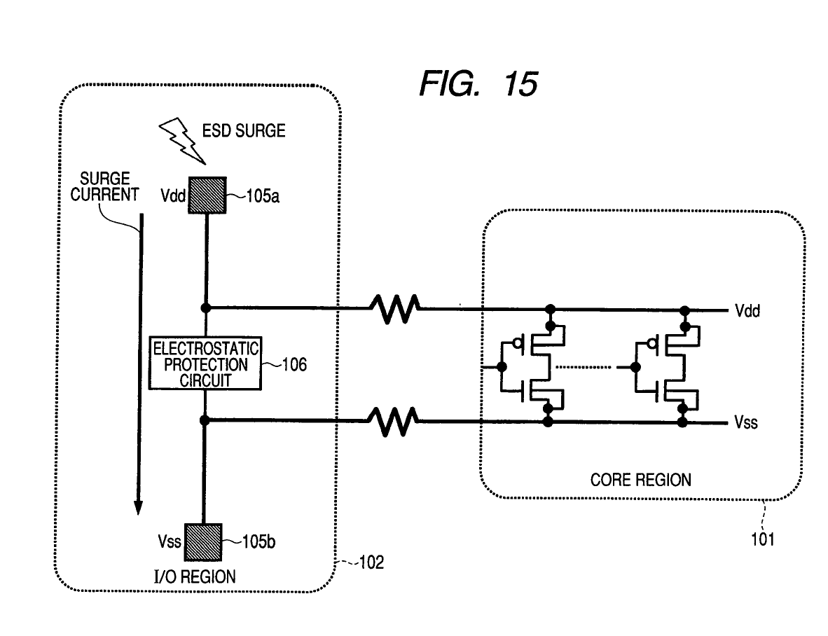

However, since the n-type impurity diffusion region 18 is longer than the p-type impurity diffusion region 17 as shown in FIG. 12, a vacant region is present on one side of the p-type impurity diffusion region 17. By effectively using the vacant region, the layout of the discharge circuit 8a shown in FIG. 13 is obtained. As shown in FIG. 13, an n-type impurity diffusion region 20 is formed in the vacant region present on one side of the p-type impurity diffusion region 17 and a larger number of n-channel MISFETs are formed in the stage subsequent to the inverter. With the layout of FIG. 13, it is possible to effectively use the vacant region and cope with a larger surge current.

Although the invention achieved by the present inventors has thus been described specifically with reference to the embodiments thereof, the present invention is not limited thereto. It will be understood that various changes and modifications can be made in the invention without departing from the gist thereof.

The present invention is widely applicable to a manufacturing industry for manufacturing a semiconductor device.

What is claimed is:

1. A semiconductor device comprising a semiconductor chip including:
(a) an I/O region in which an input/output circuit serving as an interface with an external circuit is formed; and
(b) an internal circuit region which is other than the I/O region and in which an internal circuit is formed, wherein an internal-circuit power source pad for supplying a source power to the internal circuit is formed on the internal circuit region,
wherein an electrostatic protection circuit is coupled to the internal-circuit power source pad, and
wherein a circuit composing part of the electrostatic protection circuit is formed in the internal circuit region.

2. A semiconductor device according to claim 1,
wherein the electrostatic protection circuit has a discharge circuit for discharging a surge current and a control circuit for controlling the discharge circuit, and
wherein the discharge circuit is formed in the internal circuit region.

3. A semiconductor device according to claim 2, wherein the control circuit is formed in the I/O region.

4. A semiconductor device according to claim 1,
wherein the semiconductor chip has a rectangular shape,
wherein the I/O region is formed along an outer peripheral portion of the semiconductor chip, and
wherein the internal circuit region is formed in an inner region than the I/O region.

5. A semiconductor device according to claim 4,
wherein the electrostatic protection circuit has a discharge circuit for discharging a surge current and a control circuit for controlling the discharge circuit, and
wherein the discharge circuit is formed in the internal circuit region.

6. A semiconductor device according to claim 5, wherein the control circuit is formed in the I/O region.

7. A semiconductor device according to claim 6, wherein the control circuit is formed at a corner portion of the semiconductor chip.

8. A semiconductor device according to claim 5, wherein the discharge circuit is formed in an inner peripheral portion of the internal circuit region.

9. A semiconductor device according to claim 8, wherein the discharge circuit is formed outside the internal-circuit power source pad.

10. A semiconductor device according to claim 2, wherein a plurality of the discharge circuits are coupled to the single control circuit.

11. A semiconductor device according to claim 2,
wherein the internal circuit is formed using a standard cell composed of a p-channel MISFET and an n-channel MISFET as a unit element, and
wherein the discharge circuit is formed using the standard cell.

12. A semiconductor device according to claim 11, wherein the discharge circuit is composed of an inverter and an n-channel MISFET.

13. A semiconductor device according to claim 11, wherein the discharge circuit is composed of an inverter and a plurality of n-channel MISFETs.

14. A semiconductor device according to claim 3, wherein the control circuit is composed of a resistor element and a capacitor element.

15. A semiconductor device according to claim 3,
wherein the control circuit is composed of a first MISFET and a second MISFET, and
wherein the first MISFET functions as a resistor element and the second MISFET functions as a capacitor element.
